(19) United States
(12) Patent Application Publication
(10) Pub. No.: US 2008/0230901 A1
(43) Pub. Date: Sep. 25, 2008

(54) STRUCTURE FOR CONTROLLED COLLAPSE CHIP CONNECTION WITH DISPLACED CAPTURED PADS

(75) Inventors: Eric Duchesne, Granby (CA); Julien Sylvestre, Chambly (CA)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/688,271

(22) Filed: Mar. 20, 2007

(51) Int. Cl. H01L 23/48; H01L 21/44

(52) U.S. Cl. 257/738; 438/613; 257/E23.01; 257/E21.476

(57) ABSTRACT

A structure, for controlled collapse chip connection (C4) between an integrated circuit (IC) and a substrate, that alleviates the adverse effects resulting from induced stresses in C4 solder joints, the structure includes: a first and second array defined on the ball limiting metallurgy (BLM) side of the IC; a first and second array of surface mount (SM) pads arranged on the substrate placement side; and wherein the reduction of the adverse effects resulting from the induced stress in the solder joints is facilitated by varying the relative alignment of the first and second arrays of SM pads to the first and second arrays of solder balls.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates generally to controlled collapse chip connection, and more particularly to providing a structure and method for stress reduction in solder ball attachment joints by varying alignments of solder pads in the azimuthal direction.

2. Description of the Background

Controlled-Collapse Chip Connection (C4) is a means of connecting IC (integrated circuit) chips to substrates in electronic packages. C4 is known as a flip-chip technology, in which the interconnections are small solder balls on the bottom side chip surface. C4 technology represents one of the highest density schemes known in the art for chip interconnections. The C4 technology was initially developed in the 1960s and has proven reliable in the semiconductor field. Historically, the PbSn solder for the formation of the solder ball was evaporated through a metal mask. In the 1990s, electrochemical fabrication of C4 interconnections was introduced. Electroplating is more extendible than evaporation to small C4-pad dimensions, closer pad spacing, larger wafers, and lower-melting solders (which have a higher content of Sn). More recently, the C4 new process (C4NP) technology has been developed by IBM, where bumps are first formed by injection molding in a glass mold, and later transferred to the chip. Recent years have also witnessed the introduction of lead-free alloys for c4 interconnections. These alloys are generally more resistant to plastic deformation than prior leaded versions, making them less susceptible to stress relaxation. This and other factors have resulted into the observation of new failure mechanisms on lead-free interconnections, which are generally related to the high levels of stress supported by these structures.

In general, the top layers of an integrated circuit (IC) chip are wiring levels, separated by insulating layers of dielectric material that provide input/output for the device. In C4 structures, the chip wiring is terminated by a plurality of metal films that form the ball-limiting metallurgy (BLM), which is also referred to as under-bump metallurgy (UBM). The ball-limiting metallurgy defines the size of the solder bump after reflow, provides a surface that is wettable by the solder, and that reacts with the solder to provide good adhesion and acceptable reliability under mechanical stress. The BLM also serves as a barrier between the integrated-circuit device and the metals in the interconnection.

FIGS. 1A and 1B are a typical implementation of the C4 manufacturing process. In FIG. 1A an IC 100 formed on a base material 102 (for example, silicon) has a solder ball 108 formed for subsequent attachment to a contact pad 112 (see FIG. 1B) on a carrier 114. A BLM 106 constricts the solder flow and aids in the formation of the solder ball 108 (which is formed by reflowing a deposit of solder paste), and serves as a wettable surface and contact for an underlying contact 110 for the IC 100. A passivation layer 104, typically a polymer dielectric, insulates the IC 100, and supports the BLM 106. In FIG. 1B the IC 100 is attached to the contact pad 112 on the carrier 114, by reflowing the solder ball 108. Solder flow is restricted on the carrier 114 by solder dams 116, which outline and define the contact pad 112. A secondary reflow is employed to attach the IC 100 to the contact pad 112 on the carrier 114.

However, despite the widespread use of C4 technology, implementations of new lead free solder bump alloys, BLM and chip circuitry designs have resulted in c racking and metal layer separation at the chip level after attachment to a carrier; in addition to conventional C4 fatigue under thermal cycling (TC). C4 interconnects (especially lead-free) are subject to large mechanical strains in organic packaging. The strains on the C4 solder interconnections are mostly induced by differences in coefficient of thermal expansion (CTE) between chip and carrier during assembly process and product operating conditions.

### SUMMARY OF THE INVENTION

Embodiments of the present invention include a structure for controlled collapse chip connection (C4) between an integrated circuit IC and a substrate that alleviates the adverse effects of induced stresses in solder joints of the C4. The structure includes: a first array of solder balls arranged on the ball limiting metallurgy (BLM) side of the IC; a second array of solder balls arranged on the BLM side of the IC; a first array of surface mount (SM) pads arranged on the placement side of the substrate and corresponding to the first array of solder balls on the BLM side of the IC; a second array of SM pads arranged on the placement side of the substrate and corresponding to the second array of solder balls on the BLM side of the IC; and wherein the compensation for the adverse effects of induced stress in the solder joints is facilitated by varying the relative alignment of the first and second SM pads to the first and second array of solder balls on the BLM side of the IC.

A method for controlled collapse chip connection (C4) between an integrated circuit IC and a substrate that alleviates the adverse effects of induced stresses in solder joints of the C4 is also provided. The method includes: defining a first array of solder balls arranged on the BLM side of the IC; defining a second array of solder balls arranged on the BLM side of the IC; forming a first array of surface mount (SM) pads arranged on the placement side of the substrate and corresponding to the first array of solder balls on the BLM side of the IC; forming a second array of SM pads arranged on the placement side of the substrate and corresponding to the second array of solder balls on the BLM side of the IC; varying the relative alignment of the first and second SM pad arrays to the first and second array of solder balls on the BLM of the IC; and wherein the varying facilitates the reduction of adverse effects resulting from induced stress in the solder joints.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, a solution is technically achieved in which solder attach between an IC chip and a carrier employing controlled-collapse chip connection (C4) is enhanced by alleviating adverse effects resulting from stresses induced by differences in chip to carrier coefficient of thermal expansion (CTE) by varying substrate SM pad location relative the ball limiting metallurgy (BLM).

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A is a cross sectional view of a solder ball formed on ball limiting metallurgy attached to an integrated circuit.

FIG. 1B is a cross sectional view of an integrated circuit joined to a carrier employing controlled-collapse chip connection (C4).

FIG. 2 is a top down view of a typical prior art array of substrate SM pads aligned with the C4 solder balls formed on ball limiting metallurgy attached to an integrated circuit.

FIG. 3 is a top down view that illustrates azimuthal and radial displacement of controlled-collapse chip connection (C4) according to an embodiment of the current invention.

FIG. 4 is a top down view that illustrates the relative rotation of an IC with C4 solder attachment according to an embodiment of the present invention.

FIG. 5 is a cross sectional view of a C4 solder connection in with an azimuthal offset according to an embodiment of the present invention.

FIG. 6A is a top down view of an integrated circuit (IC) chip illustrating the inner and outer regions of the IC chip according to an embodiment of the present invention.

FIG. 6B is a top down view of an integrated circuit (IC) chip illustrating a rotated inner region relative to the outer regions of the IC chip according to an embodiment of the present invention.

FIG. 7 is a top down view of offsetting relative rotation of the C4 solder attachment in the inner and outer regions of the IC chip according to an embodiment of the present invention

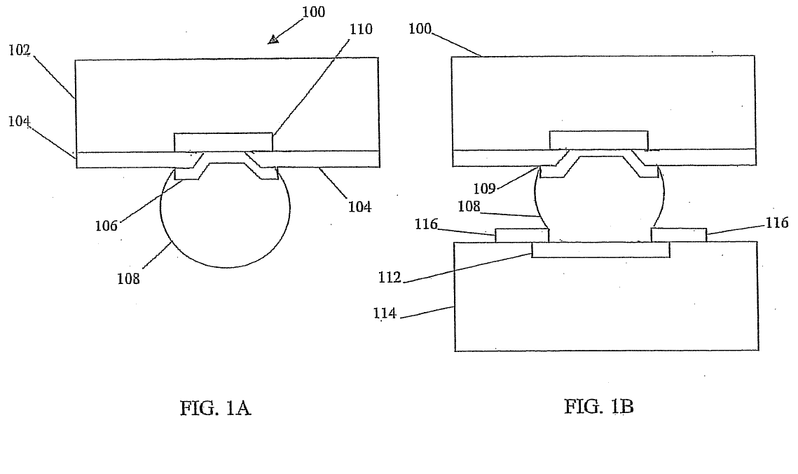

The detailed description explains the preferred embodiments of the invention, together with advantages and features, by way of example with reference to the drawings.

### DETAILED DESCRIPTION OF SPECIFIC EMBODIMENTS

Embodiments of the present invention provide a structure and method for solder attach between an IC chip and a carrier employing controlled-collapse chip connection (C4) that is enhanced by alleviating the adverse effects resulting from stresses induced by differences in chip to carrier coefficient of thermal expansion (CTE) by varying substrate SM pad locations relative the IC chip ball limiting metallurgy (BLM). The resultant azimuthal (rotational) stretching acts to increase the compliancy of the solder connections.

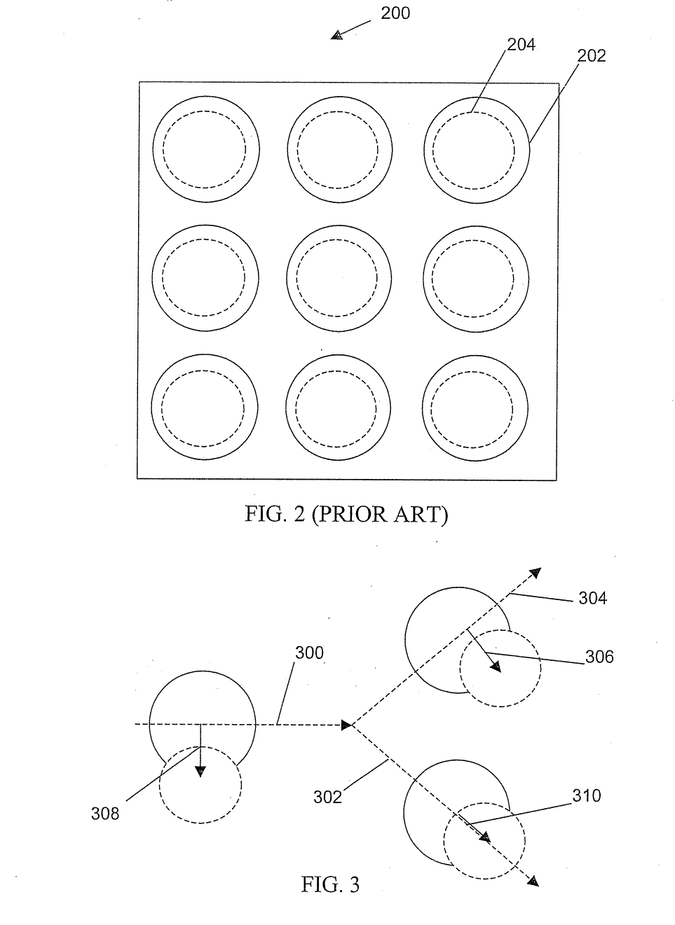

FIG. 2 is a prior art aligned ball grid array 200 that employs C4 technology to attach an IC chip to a substrate. The substrate SM pads 202 are aligned and centered to the BLM 204 (dotted lines). While it is typical for the pads and BLM to be aligned at room temperature, the alignment can also occur at a higher temperature if the design incorporates the effects of different thermal expansions in the IC and in the substrate.

FIG. 3 has two examples of azimuthal displacement, and one example of radial displacement. Embodiments of the invention mitigate the damage caused by stress by forming a solder joint that is more compliant to imposed loading in the radial direction. Radial direction is defined by the dotted lines (300, 302, 304) in FIG. 3, and are the lines joining the center of the IC to the center of the BLM. The azimuthal direction (306, 308) is the in-plane direction perpendicular to the radial direction (310). Any interconnect can have azimuthally displaced pads.

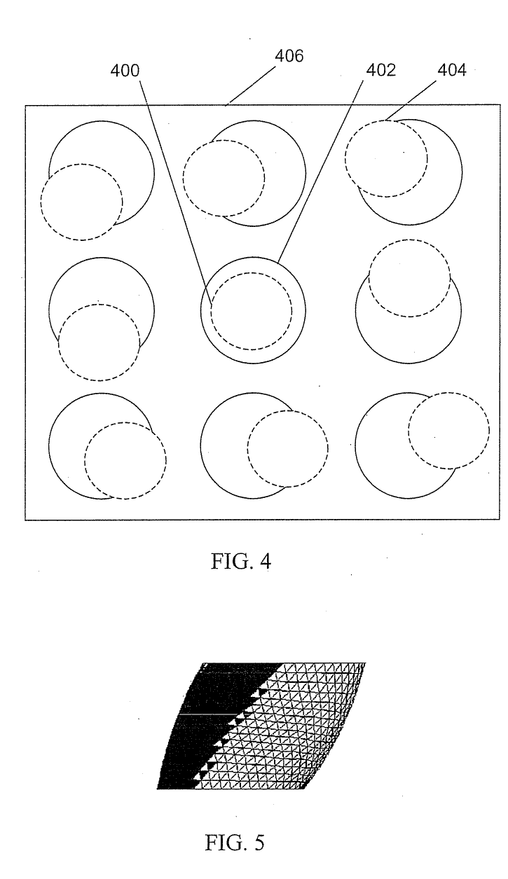

FIG. 4 illustrates azimuthal displacement of the BLM by the relative rotation of an IC chip to the SM pads on the substrate 406. The amount of azimuthal stretching increases as the distance increases from the center of the IC. At the IC center, the BLM 400 is aligned with the SM pad 402, while azimuthal stretching is observed away from the center as seen with BLM 404.

FIG. 5 is a cross sectional view of a C4 solder connection with an azimuthal offset according to an embodiment of the present invention. In an embodiment of the invention, the IC chip can be held rotationally relative to the substrate during solder attach reflow, until solder solidification.

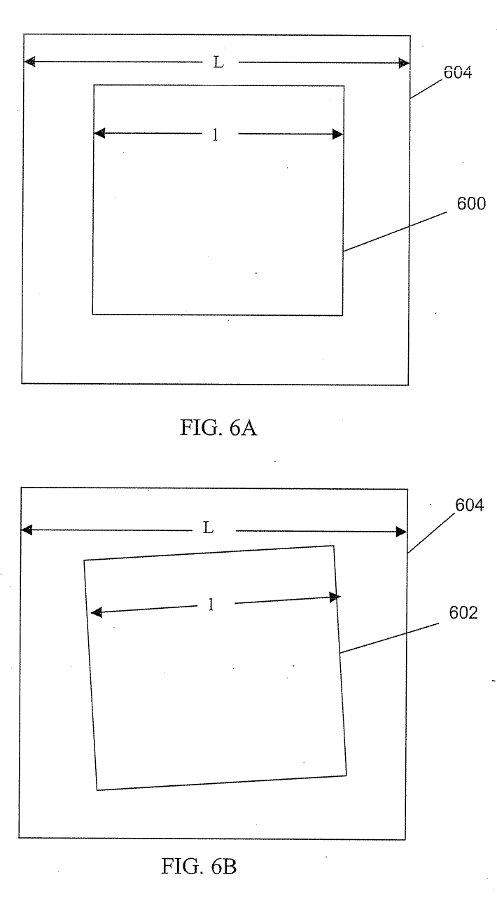

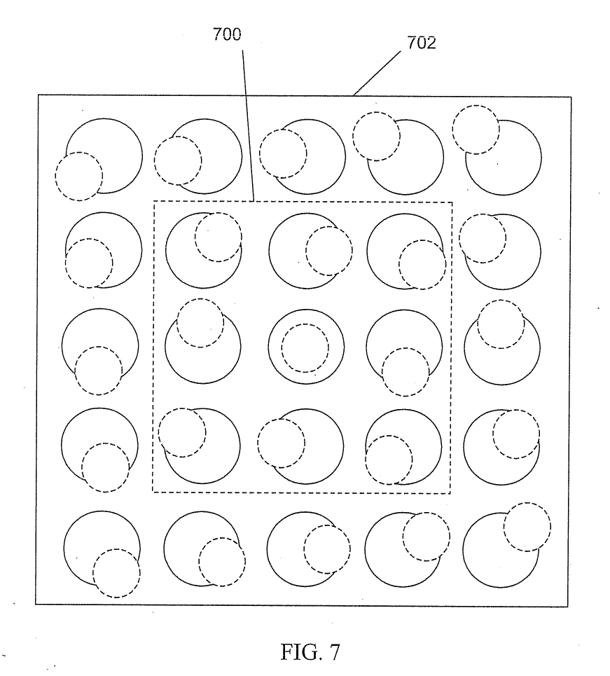

FIGS. 6A, 6B, and 7 illustrate azimuthal stretching by offsetting the array of IC chip BLM and surface mount (SM) pad centers in the azimuthal direction (Note: radial stretching is accomplished by offsetting BLM and SM pads in the radial direction) with respect to each other. Proper positioning of laminate SM pads or IC chip BLM can accomplish the azimuthal stretching. For instance, all the pads in an inner region 600 (defined by length=1) near the center of the IC Chip might be rotated by a small, fixed angle 602 (see FIG. 6B). In FIG. 7 the inner region 700 contains enough C4 to create a torque on the chip sufficient to balance the restoring torque from the C4 in the outer region 604 (defined by length L). The equilibrium position leads to high DNP C4 (outer region 702) that has a relatively large azimuthal offset. In other words, this reorients the interconnection so that it is mostly orthogonal to the radial displacement field stressing the C4s. The amount of azimuthal stretching is relatively independent of the C4 volumes in the two regions. The larger the rotated inner region, however, the larger the azimuthal stretch on high DNP C4s.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A structure for controlled collapse chip connection (C4) between an integrated circuit (IC) chip and a substrate that alleviates the adverse effects resulting from induced stresses in solder joints of the C4, the structure comprising:
a first array of solder balls arranged on a ball limiting metallurgy (BLM) side of the IC chip;
a second array of solder balls arranged on the BLM side of the IC chip;
a first array of surface mount (SM) pads arranged on a placement side of the substrate;
a second array of SM pads arranged on the placement side of the substrate; and
wherein the reduction of adverse effects resulting from the induced stress in the solder joints is facilitated by varying the relative alignment of the first and second arrays of SM pads to the first and second arrays of solder balls.

2. The structure of claim 1, wherein the relative alignment of the first array of SM pads to the first array of solder balls is offset in an azimuthal direction.

3. The structure of claim 1, wherein the relative alignment of the second array of SM pads to the second array of solder balls is offset in an azimuthal direction.

4. The structure of claim 1, wherein the relative alignment of the first array of SM pads to the first array of solder balls is offset in both an azimuthal and radial direction.

5. The structure of claim 1, wherein the relative alignment of the second array of SM pads to the second array of solder balls is offset in both an azimuthal and radial direction.

6. The structure of claim 1, wherein both the first and second arrays of the IC and SM pads are centered on the geometrical center of the IC.

7. The structure of claim 6, wherein the first and second arrays of the IC and SM pads are square shaped.

8. The structure of claim 6, wherein the first and second arrays of the IC and SM pads are rectangular shaped.

9. The structure of claim 1, wherein the first array of the IC and SM pads contains a pad that is the nearest from the geometrical center of the IC, wherein the pads in the first array form a connected clusters, and wherein the second array contains all the pads not in the first array

10. A method for controlled collapse chip connection (C4) between an integrated circuit (IC) and a substrate that compensates for the adverse effects of induced stresses in solder joints of the C4, the method comprising:
forming a first array of solder balls arranged on a BLM side of the IC;
forming a second array of solder balls arranged on the BLM side of the IC;
forming a first array of surface mount (SM) pads arranged on a placement side of the substrate;
forming a second array of SM pads arranged on the placement side of the substrate; and
varying the relative alignment of the first and second arrays of SM pads to the first and second arrays of solder balls; and
wherein the varying facilitates the reduction of the adverse effects resulting from the induced stress in the solder joints.

11. The method of claim 10, wherein the relative alignment of the first array of SM pads to the first array of solder balls is offset in an azimuthal direction.

12. The method of claim 10, wherein the relative alignment of the second array of SM pads to the second array of solder balls is offset in an azimuthal direction.

13. The method of claim 10, wherein the relative alignment of the first array of SM pads to the first array of solder balls is offset in both an azimuthal and radial direction.

14. The method of claim 10, wherein the relative alignment of the second array of SM pads to the second array of solder balls is offset in both an azimuthal and radial direction.

15. A method for controlled collapse chip connection (C4) between an integrated circuit IC and a substrate that compensates for the adverse effects of induced stresses in solder joints of the C4, the method comprising:
holding the IC at a fixed rotational angle with respect to the substrate during solder reflow of the solder joints of the C4.
